(19) United States
(12) Patent Application Publication
(10) Pub. No.: US 2024/0263310 A1
(43) Pub. Date: Aug. 8, 2024

(54) GAS-INLET ELEMENT FOR A CVD REACTOR

(71) Applicant: AIXTRON SE, Herzogenrath (DE)

(72) Inventors: Adam BOYD, Kelmis (BE); Fred Michael Andrew CRAWLEY, Hertfordshire (GB); Dominik MEYER, Aachen (DE)

(21) Appl. No.: 18/562,791

(22) PCT Filed: Jun. 1, 2022
(86) PCT No.: PCT/EP2022/064846

§ 371 Date: Nov. 20, 2023

(30) Foreign Application Priority Data
Jun. 9, 2021 (DE) 10 2021 114 868.5

(51) Int. Cl. C23C 16/455; C23C 16/30; C23C 16/46

(52) U.S. Cl. CPC C23C 16/45565; C23C 16/301; C23C 16/45572; C23C 16/46

(57) ABSTRACT

A gas-inlet element for a CVD reactor includes a gas distribution volume arranged rearward of a gas outlet plate, from which volume pipes having end portions protruding from the gas outlet plate on the front side emerge. The pipes extend into through openings in a shield plate assembly extending parallel to the gas outlet plate. The through openings have a first portion facing the gas outlet plate with a large diameter which is larger than the outer diameter of the respective end portions, and a second portion facing away from the gas outlet plate with a smaller diameter. In order to prevent temperature non-uniformities in the region of the through openings, the diameter of the second portion is smaller than the outer diameter of the respective end portions. The shield plate arrangement additionally consists of two shield plates with different thermal conductivities arranged one above another.

### RELATED APPLICATIONS

This application is a National Stage under 35 USC 371 of and claims priority to International Application No. PCT/EP2022/064846, filed 1 Jun. 2022, which claims the priority benefit of DE Application No. 10 2021 114 868.5, filed 9 Jun. 2021.

### FIELD OF THE INVENTION

The invention relates to a gas-inlet element for a CVD reactor with a first gas distribution volume arranged at the back of a gas outlet plate, wherein first pipes having end portions exiting from the gas outlet plate spring from the front side, which protrude into first through openings of a shield plate arrangement that extends parallel to the gas outlet plate, wherein the first through openings have a first section facing the gas outlet plate that has a large diameter, which is larger than the outer diameter of the end portion, and a second section facing away from the gas outlet plate with a smaller diameter.

The invention further relates to a shield plate arrangement for such a gas-inlet element.

The invention further relates to a CVD reactor with a gas-inlet element as well as to a method for depositing layers comprised of several elements onto substrates in a CVD reactor.

### BACKGROUND

DE 10 2011 056 589 A1 describes a gas-inlet element of a CVD reactor. The gas-inlet element has several gas distribution volumes, into which a process gas with a carrier gas can be fed through a respective gas supply line. The process gases can be a hydride of an element from main group V and a metalloorganic compound of an element from main group III. A noble gas, nitrogen or hydrogen can be used as the carrier gas. The gas-inlet element is cooled, and to this end has a cooling volume through which a cooling liquid flows. The gas-inlet element has a gas outlet surface, which is a broadside surface of a gas outlet plate. Each of the gas distribution volumes is connected with a plurality of pipes arranged so as to be essentially uniformly distributed over the broadside surface, with a gap between the gas outlet surface and a shield plate arrangement. The shield plate arrangement consists of a shield plate with first and second through openings, through which the process gas fed into the gap can flow through the shield plate arrangement, so as to get into a process chamber, the floor of which is composed of a susceptor and has arranged on it substrates, which are to be coated with a layer, wherein the layer consists of the two elements of the process gas. For this purpose, the susceptor is heated to a process temperature with a heating device.

Known from DE 10 2020 103 948 A1 are multipart shield plate arrangements.

The aforementioned pipes form end portions, which protrude through the through opening of the shield plate arrangement. The pipes consist of metal, and are cooled by the cooling device of the gas-inlet element to a temperature less than the temperature of the broadside surface of the shield plate arrangement facing the susceptor. These cold spots on the broadside surface facing the susceptor locally influence the growth of the layer on the susceptor.

The prior art further includes U.S. Pat. No. 6,565,661 B1, US 2007/0272154 A1, US 2005/0217582 A1, US 2005/0241579 A1, US 2015/0007770 A1 and US 2005/0255257 A1.

### SUMMARY OF THE INVENTION

The object of the invention is to diminish this influence. In particular, one object of the invention is to diminish the cold spots on the broadside surface of the shield plate arrangement facing the susceptor.

The object is achieved by the invention indicated in the claims. The subclaims do not just constitute advantageous further developments of the invention indicated in the ancillary claims, but rather also represent independent solutions to the problem.

A first aspect of the invention proposes that the through opening for at least one first pipe connected with the first gas distribution volume have two sections, which have different diameters. The first pipe has an end portion that protrudes into the first section of the through opening. This first section of the through opening has an inner diameter that is larger than the outer diameter of the end portion of the first pipe that protrudes in there. A second section of the through opening has a smaller diameter. In particular, the diameter of the second section is smaller than the outer diameter of the end portion. The diameter of the second section of the through opening can correspond roughly to the inner diameter of the first f pipe. In particular, it is provided that the shield plate arrangement be formed by a single shield plate. This shield plate can have a plurality of stepped bores, which form the first through openings. The stepped bores are arranged so as to be uniformly distributed over the broadside surfaces of the shield plate. Second through openings allocated to second pipes can be arranged between the first through openings. The second pipes can likewise have end portions that protrude into sections of the second through openings with an enlarged diameter. However, the second pipes can also end flush with the gas outlet surface. The second pipes are connected with a second gas distribution volume, into which a second process gas can be fed. In particular, it is provided that a process gas of an element from main group III flow through the first pipes and through the first through openings. A process gas of an element from main group V can flow through the second pipes and the second through openings. The second through openings preferably align with the openings of the second pipes. The shield plate arrangement can have a broadside surface facing the gas outlet plate, which is spaced apart from the gas outlet plate. This distance can be smaller than an immersion depth of the end portion into the through opening. In particular, the distance is smaller than the axial length of the end portion of the first or second pipe that protrudes from the gas outlet plate. The material thickness of the gas outlet plate can range between 3 and 6 mm. A preferred material thickness is 5.5 mm. The gas outlet plate can adjoin a cooling volume, through which a cooling liquid flows. The cooling liquid can have a temperature between 50 and 70° C., preferably measuring about 60° C. The distance by which the shield plate arrangement is spaced apart from the gas outlet plate can range between 0.2 and 2 mm. A preferred distance is 0.5 mm. The two sections of the through openings can be cylindrical in design, so that a step forms in the border area of the two sections with the different diameters. The step can lie in the axial center of the through opening. The axial length of the section having the larger diameter can measure 2 to 5 mm. A preferred depth of the large-diameter section of the through opening can measure 3 mm or 4.6 mm. The thickness of the shield plate arrangement and in particular the thickness of a single shield plate forming the shield pate arrangement can lie within a range of between 4 mm and 10 mm. A preferred thickness of the shield plate arrangement measures 6 or 8 mm. The axial length of the end portion of the pipe protruding into the through opening can lie within a range of between 2 and 7 mm. A preferred length can measure 3.5 mm or 5 mm. The shield plate can consist of SiC. However, it is preferred that the shield plate or several plates of the shield plate arrangement consist (s) of graphite, wherein such a shield plate can be coated with SiC. Means can be provided to alter the distance between the shield plate or shield plate arrangement and the gas outlet plate. Provided in particular is a lifting device, which can be used to set this distance. In particular, the distance is set in such a way that the surface temperature of the shield plate or shield plate arrangement facing the process chamber measures about 250° C. The length of the large-diameter section of the through opening and the length of the end portion or its immersion depth into the large-diameter section of the through opening is preferably selected in such a way that the surface temperature of the shield plate lies in a range of between 100° C. and 300° ° C., depending on the process performed in the process chamber. In a cleaning process during which the distance between the shield plate arrangement and gas outlet plate is enlarged, the surface temperature can also reach 850° C.

According to a second aspect of the invention, the shield plate arrangement has two sections. To this end, the shield plate arrangement can consist of two individual shield plates, which physically abut against each other or are spaced slightly apart from each other on facing broadside surfaces. It is essential that one section of the shield plate arrangement have a low thermal conductivity, i.e., act as a kind of thermal insulator. According to a preferred embodiment of the invention, the shield plate that adjoins the gas outlet plate directly or with the formation of a gap consists of a thermally insulating material, for example quartz. By contrast, the shield plate facing the process chamber can consist of a readily thermally conductive material, for example graphite or coated graphite. The shield plate arrangement having two sections with different thermal conductivity properties can also have the features of the first aspect of the invention, i.e., in particular form through openings for the process gas that have sections with diameters differing from each other. It can here be provided that an upper shield plate facing the gas outlet plate have the sections with the largest diameters, and another shield plate facing the process chamber have the sections of the through openings with the smallest diameters. However, the sections with the largest diameters can also extend until into a lower shield plate, so that the end portions of the pipes extend through through openings of the upper shield plate until into coarser sections of the through openings of the lower shield plate. It can also be provided that the upper shield plate have alternating through openings with different diameters. The first pipes protrude into the through openings with the largest diameters. The second pipes for a second process gas open into the lower broadside surface of the gas outlet plate.

The shield plate arrangement according to the invention or the CVD reactor according to the invention or the gas-inlet element according to the invention can additionally also have the following features: The outline of the gas outlet surface has a circular shape. The outline of the shield plate arrangement has a circular surface. The shield plate arrangement can have a central area. The central area can be surrounded by an edge area. The shield plate arrangement can consist of one or several shield plates arranged one on top of the other. The end portions can have a larger length in the central area than in the edge area. The end portions can have a larger length in the edge area than in the central area. The first sections of the first or second through openings can have the same diameter and the same axial depth over the entire surface of the shield plate arrangement. However, it is also provided that the first sections of the first or second through openings have a different depth in the central area than in the edge area. It can be provided that the first and/or second sections of the first and/or second through openings be identical in design over their entire respective axial length. In particular, the sections can be shaped like a cylinder. The outline of the first and second sections of the first and/or second passage bores can be a circular shape. It can further be provided that the first or second passage bores each expand like a funnel toward the respective broadside surface.

The invention relates to a method for depositing several layers comprising several components onto substrates, wherein the components in particular are different elements, and in particular elements from main groups III and V. The method is characterized in that use is made of a gas-inlet element or a shield plate arrangement or a CVD reactor of the kind described previously, wherein the shield plate arrangement, if it has a uniform thermal conductivity, can be materially uniform in design, consisting of one shield plate, and wherein the shield plate arrangement, if it has sections varying in thermal conductivity, can consist of two shield plates. In particular, it is provided that pipes carrying a flow of a process gas containing an element of main group III, in particular a metalloorganic compound of main group III, have end portions that protrude into stepped bores of a shield plate, wherein the stepped bore has a section that has a diameter smaller than the outer diameter of the end portion of the pipe. It can further be provided that pipes carrying a flow of a process gas having an element of main group V, in particular a hydride of an element of main group V, have no end portions that protrude into bores of the shield plate. However, it can also be provided that these second pipes likewise have end portions that protrude into stepped bores. The aforementioned features or at least some of these features improve the temperature inhomogeneity on the side of the shield plate arrangement facing the process chamber. According to the invention, the diameter of the second section is smaller than the diameter of the front face of the end portion, so that the end portion can plunge into the first section at most until the floor of the first section of the first through opening.

### BRIEF DESCRIPTION OF THE DRAWINGS

Exemplary embodiments of the invention will be described below based on the attached drawings. Shown on:

FIG. 1 is a schematic view of a CVD reactor,

FIG. 2 is a cutout of a gas-inlet element 2 of a first exemplary embodiment of the CVD reactor shown on FIG. 1, wherein a broadside surface 10″ of a shield plate 10 has a small distance D to a gas outlet surface 3′,

FIG. 3 is an illustration according to FIG. 2, wherein the distance D is enlarged,

FIG. 4 a further enlarged view of a cutout of the gas-inlet element shown on FIG. 2,

FIG. 5 is an illustration according to FIG. 2 of a second exemplary embodiment,

FIG. 6 is an illustration according to FIG. 2 of a third exemplary embodiment,

FIG. 7 is an illustration according to FIG. 2 of a fourth exemplary embodiment,

FIG. 8 is an illustration according to FIG. 2 of a fifth exemplary embodiment,

FIG. 9 is an illustration according to FIG. 2 of a sixth exemplary embodiment, and

FIG. 10 is an illustration according to FIG. 2 of a seventh exemplary embodiment.

### DETAILED DESCRIPTION

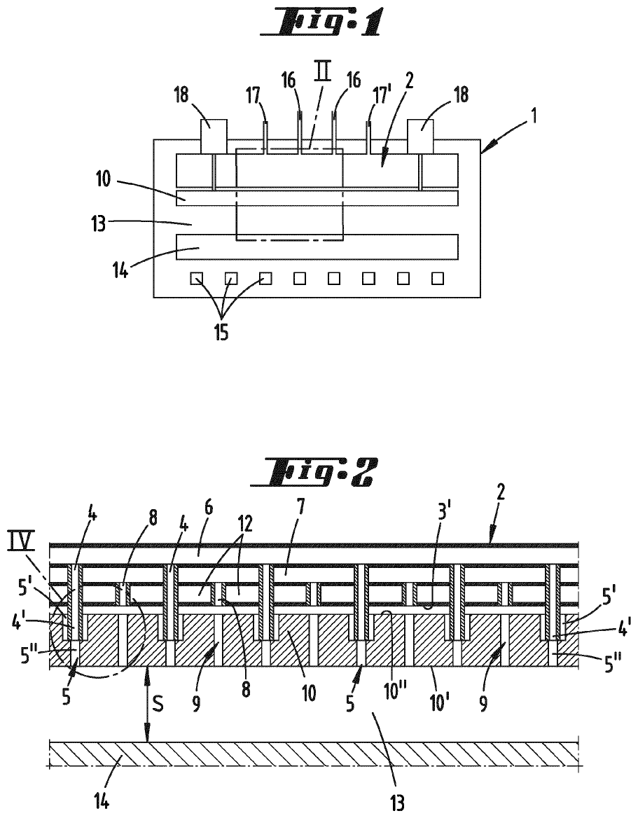

FIG. 1 schematically shows a CVD reactor for depositing III-V layers onto substrates. Located in a reactor housing of the CVD reactor 1 is a susceptor 14, which can consist of coated graphite, and which can be heated to process temperatures of 850 to 1200° ° C. by a heating device 15. The heating device 15 can be an infrared heater, an RF-heater, or a resistance heater. The broadside surface of the susceptor 14 facing away from the heating device 15 is used to support the substrates that are coated in a process chamber 13. The process chamber 13 downwardly bounded by the susceptor 14 is upwardly bounded by a gas-inlet element 2. The height S of the process chamber 13 can lie within a range of 7 to 15 mm. A preferred height S measures about 11 mm. The gas-inlet element consists of an upper section comprised in particular of metal, in which gas distribution volumes 6, 7 are arranged. Gas supply lines 16 can be used to feed the process gas into the gas distribution volumes 6, 7 from outside. One of the two process gases is preferably fed into each of the gas distribution volumes 6, 7, wherein the respective process gas can consist of a reactive gas, for example a metalloorganic compound of an element of main group III or a hybrid of an element of main group V and hydrogen.

FIG. 2 shows a first exemplary embodiment of a gas-inlet element 2, in which a first gas distribution volume 6, for example into which the III-component can be fed, is flow connected with the process chamber 13 via first pipes 4. A second gas distribution volume 7 is likewise flow connected with the process chamber 13 via second pipes 8. Both pipes 4, 8 extend through a cooling volume 12, into which a cooling liquid can be fed by means of a supply line 17, which again exits the cooling volume 12 through a drain 17′. The cooling device designed in this way is used to cool the gas outlet plate 3, which forms a gas outlet surface 3′ on its side facing the process chamber 13.

A shield plate arrangement extends between the susceptor 14 and the gas outlet surface 3′, which in the first exemplary embodiment shown on FIGS. 2 and 3 consists of a single shield plate 10 made of graphite. The shield plate 10 is coated with SiC. The shield plate 10 has a broadside surface 10″, which is spaced apart from the gas outlet surface 3′ by a distance D. The distance can measure 0.5 mm.

FIG. 2 shows a first exemplary embodiment of a gas-inlet element 2, in which a first gas distribution volume 6, for example into which the III-component can be fed, is flow connected with the process chamber 13 via first pipes 4. A second gas distribution volume 7 is likewise flow connected with the process chamber 13 via second pipes 8. Both pipes 4, 8 extend through a cooling volume 12, into which a cooling liquid can be fed by means of a supply line 17, which again exits the cooling volume 12 through a drain 17′. The cooling device designed in this way is used to cool the gas outlet plate 3, which forms a gas outlet surface 3′ on its side facing the process chamber 13.

A shield plate arrangement extends between the susceptor 14 and the gas outlet surface 3′, which in the first exemplary embodiment shown on FIGS. 2 and 3 consists of a single shield plate 10 made of graphite. The shield plate 10 is coated with SiC. The shield plate 10 has a broadside surface 10″, which is spaced apart from the gas outlet surface 3′ by a distance D. The distance can measure 0.5 mm.

The shield plate 10 has first and second through openings 5, 9, which are uniformly distributed over the entire surface of the shield plate 10. The first through openings 5 have a first section 5′, which has a large diameter and a circular cylindrical interior. A second section 5″ having a smaller diameter adjoins the first section 5′ with the formation of a step. This second section can also have a circular cylindrical interior. While the first section 5′ opens in the direction of the gas outlet plate 3, the second section 5″ opens into a broadside surface 10′ of the shield plate 10 facing away from the gas outlet plate 3.

The second through openings 9 have a constant, circular cross section over their entire length, and a diameter corresponding to roughly the diameter of the second section 5″.

A shown in FIG. 4, the first pipes 4 each have an end portion 4′ that protrudes over the gas outlet surface 3′. The length L with which the end portion 4′ protrudes over the gas outlet surface 3′ preferably measures about 3.5 mm in the exemplary embodiment. The depth P of the first section 5′ of the through opening 5 can measure 3 mm. The material thickness B of the shield plate 10 can measure 6 mm.

The front face of the end portion 4′ can be spaced apart from the floor of the first section 5′. However, the front face of the end portion 4′ contacts the floor 5′″ of the first section 5′ in the exemplary embodiment. The immersion depth T in this exemplary embodiment corresponds to the depth P of the first section 5′. If the front face of the end portion 4′ is spaced apart from the floor of the first section 5′, the immersion depth T is smaller than the depth P of the first section 5′. The diameter of the second section 5″ is smaller than the outer diameter of the end portion 4′, and can roughly correspond to the inner diameter of the first pipe 4. The diameter can be slightly smaller than the inner diameter of the first pipe 4 or slightly larger than the inner diameter of the first pipe 4.

The mouth openings of the second pipes 8 are spaced apart from the openings of the second through openings.

The distance D can be enlarged with a lifting device marked with reference number 18 on FIG. 1. This diminishes the cooling effect of the cooling device of the cooling volume 12 on the shield plate 10, so that it can be lowered from the position shown on FIG. 2 into the operating position shown on FIG. 3, for example to perform an etching step in which the broadside surface 10′ of the shield plate 10 is cleaned. While the surface temperature of the broadside surface 10″ measures about 250° C. in the operating position shown on FIGS. 1 and 2, the surface temperature of the broadside surface 10″ can reach in excess of 800° in the operating position shown on FIG. 3.

The exemplary embodiment shown on FIG. 5 essentially only differs from the first exemplary embodiment shown on FIGS. 2 to 4 in that the second pipes also extend into first diameter-enlarged sections 9″ of the second through openings 9 in the manner described above. Here as well, the front faces of the second pipes can abut against floors of the second through openings, or be spaced apart from the floors of the second through openings 9. The diameters of the second sections 9″ of the second through openings are here also smaller than the outer diameters of the end portions 8′ of the second pipes that protrude into the first sections 9′ of the second through openings 9.

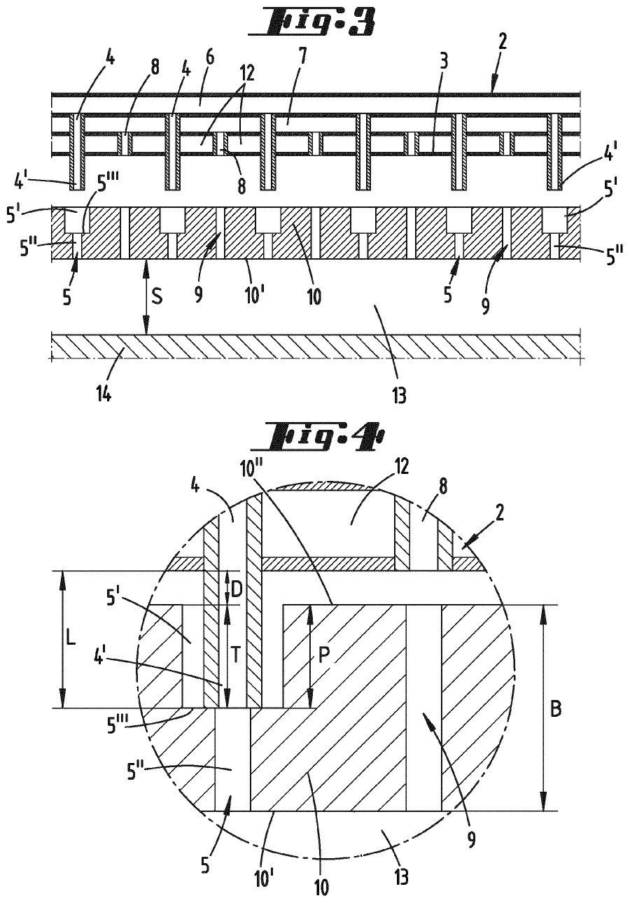

In the exemplary embodiment shown on FIG. 6, the end portions 4′ in a central area Z of an essentially circular disk-shaped shield plate 10 have a smaller penetration depth into the first through openings 5 than in an edge area R that surrounds the central area Z.

In the exemplary embodiment shown on FIG. 7, the end portions 4′ in a central area Z of an essentially circular disk-shaped shield plate 10 have a larger penetration depth into the first through openings 5 than in an edge area R that surrounds the central area Z.

The exemplary embodiment shown on FIG. 8 essentially differs from the exemplary embodiments described previously in that the first and/or second through openings 5, 9 expand like a funnel toward either the broadside surface 10″ or toward the broadside surface 10′ of the shield plate. The second sections 5″ of the through openings 5 can expand like a funnel both toward the floor 5′″ and toward the broadside surface 10′.

FIG. 8 presents an image showing several different constellations of through openings 5, 9, which can have funnel-shaped expansions. In an exemplary embodiment, each of the first through openings 5 and each of the second through openings 9 have the same shape.

The exemplary embodiments shown on FIGS. 9 and 10 initially differ from the exemplary embodiments described previously in that a shield plate arrangement has two shield plates 10, 11 instead of a materially uniform shield plate arrangement comprised of only one shield plate 10. An upper shield plate 10 facing the gas outlet plate 3 can be fabricated out of a poorly thermally conductive material, for example quartz, and thus comprise a thermal insulator. A lower shield plate 11 facing away from the gas outlet plate 3 and toward the process chamber 13 and in particular adjoining the process chamber 13 can consist of a readily thermally conductive material, for example graphite. In particular, the lower shield plate 11 has a specific thermal conductivity that exceeds that of the upper shield plate 10 by a factor of 5, 10, 20. The two shield plates 10, 11 can physically abut against each other. However, they can also be spaced a distance apart from each other. The two shield plates 10, 11 each have through openings 5, 9, wherein the upper shield plate 10 forms an upper section 5′, 9′ of a through opening 5, 9, and the lower shield plate 11 forms a respective lower section 5″, 9″ of a through opening 5, 9.

In the exemplary embodiment shown on FIG. 9, the upper sections 5′, 9′ each have the same cross sectional surface as the lower sections 5″, 9″ allocated to them. The first pipes 4 and the second pipes 8 open into the gas outlet surface 3′ in this exemplary embodiment.

In the exemplary embodiment shown on FIG. 10, end portions 4′ of the first pipe 4 protrude into the upper sections 5′ of the first through openings 5, as was described above with reference to the exemplary embodiments shown on FIGS. 2 to 8. In this exemplary embodiment, the large-diameter sections 5′ are formed by the upper shield plate 10, and smaller-diameter sections 5″ by the lower shield plate 11. The shield plates 10, 11 can have the same thickness. However, they can also have a different material thickness. Here as well, it can be provided that the front faces of the end portions 4′ physically abut against the broadside surface 11′ of the lower shield plate 11 or, as shown on FIG. 10, be spaced apart therefrom.

The above statements serve to explain the inventions covered by the application as a whole, which each also independently advance the prior art at least by the following feature combinations, wherein two, several or all of these feature combinations can also be combined, specifically:

A gas-inlet element, characterized in that the diameter of the second section 5″ is smaller than the outer diameter of the end portion 4′.

A gas-inlet element, characterized in that the shield plate arrangement has a first section 10 with a low thermal conductivity facing the gas outlet plate 3, and an adjoining second section 11 with a high thermal conductivity facing away from the gas outlet plate 3.

A gas-inlet element, characterized in that the end portions 4′ of the first pipes 4 protrude into the first through openings 5′ of the first section 10 of the shield plate arrangement and/or that the shield plate arrangement has two shield plates 10, 11 with different thermal conductivities, which have broadside surfaces 10′, 11′ that adjoin each other, contact each other, or are spaced apart from each other by a gap, and/or that the first section 10 of the shield plate arrangement consists of quartz, and the second section 11 of the shield plate arrangement consists of graphite or coated graphite.

A gas-inlet element, characterized in that an upper broadside surface 10″ of the shield plate arrangement 10, 11 facing the gas outlet plate 3 has a distance D to a lower broadside surface 3′ of the gas outlet plate 3, and/or that the distance D is smaller than the immersion depth T of the end portion 4′ into the first through opening 5.

A gas-inlet element, characterized in that a second gas distribution volume 7 of the gas-inlet element is flow connected with second pipes 8, whose openings facing away from the second gas distribution volume 7 are directed toward second through openings 9 of the shield plate arrangement 10, 11, and/or that the gas outlet plate 3 can be cooled by a cooling device 12, and/or that a cooling volume 12 through which a cooling liquid can flow adjoins the gas outlet plate 3.

A gas-inlet element, characterized in that end portions 8′ of the second pipes 8 protrude into large-diameter first sections 9″ of the second through openings 9, and second sections 9′ of the second through openings 9 have a smaller diameter than the outer diameter of the end portions 8′ of the second pipes 8.

A gas-inlet element, characterized in that the shield plate arrangement 10, 11 has a central area Z, wherein the end portions 4′, 8′ of the first and/or second pipes 4, 8 plunge more deeply or less deeply into the first or second through openings 5, 9 in the central area Z of the shield plate arrangement 10, 11 than in an edge area R of the shield plate arrangement 10, 11 surrounding the central area Z.

A gas-inlet element, characterized in that the first and/or second through openings 9 expand like a funnel toward the broadside surface 10″ of the shield plate arrangement 10, 11 facing the gas outlet plate 3 or toward the broadside 10′ of the shield plate arrangement 10, 11 facing away from the gas outlet plate 3, and/or that a cylindrical area 5′, 9′ of the first section of the first and/or second through opening 5, 9 adjoins a cylindrical area 5″, 9″ of the second section of the first and/or second through opening 5, 9, with the formation of a step.

A shield plate arrangement, characterized in that the first broadside surface 10″ of the shield plate arrangement 10, 11 is comprised of a section with a low thermal conductivity, and the second broadside surface 11″ of the shield plate arrangement 10, 11 is comprised of a section with a high thermal conductivity, and/or that the through openings 5, 9 have sections 5′, 5″, 9′, 9″ with different diameters.

A CVD reactor, characterized in that the gas-inlet element 2 is designed according to one of the preceding claims.

A method, characterized in that the gas-inlet element 2 is designed according to one of the preceding claims.

A method, characterized in that a reactive gas of an element of main group III is fed into the first pipes 4, and a reactive gas of main group V is fed into the second pipes 8.

All disclosed features (whether taken separately or in combination with each other) are essential to the invention. The disclosure of the application hereby also incorporates the disclosure content of the accompanying/attached priority documents (copy of the prior application) in its entirety, also for the purpose of including features of these documents in claims of the present application. Even without the features of a referenced claim, the subclaims characterize standalone inventive further developments of prior art with their features, in particular so as to submit partial applications based upon these claims. The invention indicated in each claim can additionally have one or several of the features indicated in the above description, in particular those provided with reference numbers and/or indicated on the reference list. The invention also relates to design forms in which individual features specified in the above description are not realized, in particular if they are recognizably superfluous with regard to the respective intended use, or can be replaced by other technically equivalent means.

### REFERENCE LIST

| | |
|---|---|
| 1 | CVD reactor |
| 2 | Gas-inlet element |
| 3 | Gas outlet plate |
| 3′ | Gas outlet surface |
| 4 | First pipe |
| 4′ | End portion |
| 5 | First through opening |
| 5′ | Section with a large |
| | diameter |
| 5″ | Section with a small |
| | diameter |
| 5″′ | Floor |
| 6 | First gas distribution |
| | volume |
| 7 | Second gas distribution |
| | volume |
| 8 | Second pipe |
| 8′ | End portion |
| 9 | Second through opening |
| 9′ | Section with a large |
| | diameter |
| 9″ | Section with a small |
| | diameter |
| 10 | Shield plate |
| 10′ | Broadside surface |
| 10″ | Broadside surface |
| 11 | Shield plate |
| 11′ | Broadside surface |
| 11″ | Broadside surface |
| 12 | Cooling volume |
| 13 | Process chamber |
| 14 | Susceptor |
| 15 | Heating device |
| 16 | Gas supply line |
| 17 | Cooling liquid supply |
| | line |
| 17′ | Cooling liquid drain |
| 18 | Lifting device |

1. A gas-inlet element (2) for a chemical vapor deposition (CVD) reactor (1), the gas-inlet element (2) comprising:
a gas outlet plate (3);
a shield plate arrangement (10, 11) extending parallel to the gas outlet plate (3) and comprising first through openings (5);
a first gas distribution volume (6) facing a first side of the gas outlet plate (3);
first pipes (4) having respective end portions (4′) protruding from a second side of the gas outlet plate (3) opposite to the first side, and extending into the first through openings (5) of the shield plate arrangement (10, 11),
wherein the first through openings (5) each have a first section (5′) and a second section (5″), the first section (5′) disposed between the gas outlet plate (3) and the second section (5″),
wherein a diameter of the first section (5′) is larger than an outer diameter of the respective end portions (4′), and is larger than a diameter of the second section (5″), and
wherein the diameter of the second section (5″) is smaller than the outer diameter of the respective end portions (4′), which either (i) abuts against a floor of the first section (5′) or (ii) is spaced apart therefrom so that an immersion depth (T) of the respective end portions (4′) into the first section (5′) of each of the first through openings (5) is smaller than a depth (P) of the first section (5′).

2. A gas-inlet element (2) for a chemical vapor deposition (CVD) reactor (1), the gas-inlet element (2) comprising:
a gas outlet plate (3);
a first gas distribution volume (6) facing a first side of the gas outlet plate (3);
first pipes (4) having respective end portions (4′) protruding from a second side of the gas outlet plate (3);
a shield plate arrangement (10, 11) that extends parallel to the gas outlet plate (3) and faces a second side of the gas outlet plate (3) opposite to the first side, the shield plate arrangement (10, 11) with at least one shield plate and first through openings (5),
wherein the shield plate arrangement (10, 11) has a first section (10) with a first thermal conductivity and an adjoining second section (11) with a second thermal conductivity that is higher than the first thermal conductivity, and
wherein the first section (10) is disposed between the gas outlet plate (3) and the second section (11).

3. The gas-inlet element (2) of claim 2, wherein at least one of:
(i) the respective end portions (4′) of the first pipes (4) protrude into the respective first through openings (5) of the shield plate arrangement (10, 11);
(ii) the first section (10) comprises a first shield plate (10), the second section (11) comprises a second shield plate (11), and the first and second shield plates (10, 11) have respective broadside surfaces (10′, 11′) that adjoin each other, contact each other, or are spaced apart from each other by a gap; or
(iii) the first section (10) of the shield plate arrangement (10, 11) consists of quartz, and the second section (11) of the shield plate arrangement (10, 11) consists of graphite or coated graphite.

4. The gas-inlet element (2) of claim 1, wherein a first broadside surface (10″) of the shield plate arrangement (10, 11) facing the gas outlet plate (3) is separated from a broadside surface (3′) of the gas outlet plate (3) by a distance (D).

5. The gas-inlet element (2) of claim 4, wherein the distance (D) is smaller than the immersion depth (T).

6. The gas-inlet element (2) of claim 1, further comprising a second gas distribution volume (7) that is flow connected with second pipes (8), whose openings facing away from the second gas distribution volume (7) are directed toward second through openings (9) of the shield plate arrangement (10, 11).

7. The gas-inlet element (2) of claim 1, further comprising a cooling device (12) for cooling the gas outlet plate (3).

8. The gas-inlet element (2) of claim 1, further comprising a cooling volume (12) that adjoins the gas outlet plate (3), the cooling volume (12) for containing a cooling liquid.

9. The gas-inlet element (2) of claim 6, wherein respective end portions (8′) of the second pipes (8) each protrude into respective first sections (9′) of the second through openings (9), and respective second sections (9″) of the second through openings (9) each have a smaller diameter than an outer diameter of the respective end portions (8′) of the second pipes (8).

10. The gas-inlet element (2) of claim 6,
wherein the shield plate arrangement (10, 11) has a central area (Z), and
wherein the respective end sections-portions (4′) of the first pipes (4) plunge more deeply or less deeply into the first through openings (5) and/or the respective end portions (8′) of the second pipes (8) plunge more deeply or less deeply into the second through openings (9) in the central area (Z) of the shield plate arrangement (10, 11) than in an edge area (R) of the shield plate arrangement (10, 11) surrounding the central area (Z).

11. The gas-inlet element (2) of claim 6, wherein one or more of the first through openings (5) or the second through openings (9) expand like a funnel (i) toward a first broadside surface (10″) of the shield plate arrangement (10, 11) facing the gas outlet plate (3) or (ii) toward a second broadside surface (10′) of the shield plate arrangement (10, 11) facing away from the gas outlet plate (3).

12. The gas-inlet element (2) of claim 9, wherein at least one of:
(i) a cylindrical area of the first section (5′) of the first through opening (5) adjoins a cylindrical area of the second section (5″) of the first through opening (5) with a first step; or
(ii) a cylindrical area of the first section (9′) of the second through opening (9) adjoins a cylindrical area of the second section (9″) of the second through opening (9) with a second step.

13. The gas-inlet element (2) of claim 1,
wherein the shield plate arrangement (10, 11) includes a first broadside surface (10″) and a second broadside surface (11″) running parallel to each other,
wherein the first through openings (5) extend between the first broadside surface (10″) and the second broadside surface (11″) and are uniformly distributed over the first broadside surface (10″) and the second broadside surface (11″), and
wherein the first broadside surface (10″) of the shield plate arrangement (10, 11) is comprised of a section with a first thermal conductivity, and the second broadside surface (11″) of the shield plate arrangement (10, 11) is comprised of a section with a second thermal conductivity higher than the first thermal conductivity.

14. (canceled)

15. A chemical vapor deposition (CVD) reactor (1), comprising:
a susceptor (14);
a heating device (15) for heating the susceptor (14);
the gas-inlet element (2) of claim 1; and
a process chamber (13) located between the shield plate arrangement (10, 11) and the susceptor (14),
wherein the susceptor (14) carries substrates that are coated in the process chamber (13).

16. A method for depositing layers having several components onto substrates, which are carried by a heated susceptor (14) of a chemical vapor deposition (CVD) reactor (1), the method comprising feeding a process gas having at least two components from the gas-inlet element (2) of claim 1 into a process chamber (13) bounded by the heated susceptor (14) and the shield plate arrangement (10, 11).

17. The method of claim 16, wherein a first reactive gas with an element from main group III is fed into the first pipes (4), and a second reactive gas with an element from main group V is fed into second pipes (8) of the gas-inlet element (2).

18. (canceled)
